(19) United States
(12) Patent Application Publication
(10) Pub. No.: US 2009/0173939 A1
(43) Pub. Date: Jul. 9, 2009

(54) Hybrid Wafers

(76) Inventors: Sören Berg, Uppsala (SE); Jörgen Olsson, Uppsala (SE); Örjan Vallin, Uppsala (SE); Ulf Smith, Huddinge (SE)

Correspondence Address: PORTER WRIGHT MORRIS & ARTHUR, LLP;INTELLECTUAL PROPERTY GROUP, 41 SOUTH HIGH STREET, 28TH FLOOR, COLUMBUS, OH, 43215, US

(21) Appl. No.: 12/298,336

(22) PCT Filed: Apr. 23, 2007
(86) PCT No.: PCT/IB07/01087

§ 371 Date: Oct. 24, 2008

Related U.S. Application Data
(60) Provisional application No. 60/794,380, filed on Apr. 24, 2006.

(51) Int. Cl. H01L 29/12

(52) U.S. Cl. 257/49; 257/E21.703; 257/19; 257/E29.068; 257/7

(57) ABSTRACT

A hybrid wafer comprises a single-crystal SiₓGe₁₋ₓ layer (15), where 0≦x≦1, a high thermal conductivity layer (10), and between the single-crystal SiₓGe₁₋ₓ layer (15) and the high thermal conductivity layer (10), an intermediate layer (21) having a thickness of between 1 nanometer and 1 micrometer and comprising at least one amorphous or polycrystalline SiₓGe₁₋ₓ layer (21a), where 0≦x≦1.

### TECHNICAL FIELD

The invention relates generally to wafers for production of integrated circuits and, more specifically, to hybrid wafers.

### BACKGROUND OF THE INVENTION

The limited thermal conductivity of silicon (Si) can cause overheating problems when high-power components are present in an integrated circuit (IC). As a consequence, Si components cannot be close-packed to extents that would be desirable from performance and economical points of view. The poor thermal conductivity of Si also puts limits on the power permitted in discrete Si components. The only way to circumvent these limits is to resort to advanced cooling methods. Examples of applications where the limited thermal conductivity forms a serious obstacle to further technical development are power modules in communication systems for mobile telephony, broadcasting, as well as transmitter modules in radar systems.

The problem grows even worse if the components have to be electrically insulated from the substrate. This is usually achieved by means of an intermediate layer of silicon dioxide (SiO₂). However, the thermal conductivity of such a layer is 100 times worse than that of Si. An example of such insulation is the commercially available hybrid wafer “Silicon-on-Insulator” (SOI), where a crystalline layer of Si is insulated from the underlying Si wafer by a layer of SiO₂. The problem with a limited thermal conductivity can be solved to some extent if a wafer made from the insulator sapphire is used, since the thermal conductivity of sapphire is almost 25 times that of SiO₂. The single-crystal Si layer is grown directly on the sapphire to form the commercially available “Silicon-on-Sapphire” (SOS) wafer. However, a large part of the thermal transport problem remains, since the sapphire has to be made quite thick in order to provide the necessary mechanical strength. Thus the increase in thermal conductivity is negated by a longer path for the heat transport. As a consequence, SOS wafers will not be able to satisfy the steadily rising demands for increased performance. Furthermore, the electrical properties of the Si layer grown on the surface of the SOS wafer are inferior to those of bulk Si. Having the bulk of the wafer made of an insulator also poses the limitation that semiconductor components cannot be integrated in the SOS wafer itself, in contrast to the situation for SOI wafers. In the latter case, a removal of the Si-layers and the SiO₂-layers in selected areas makes it possible to have components in the Si layer and the Si substrate on the same chip. The component parts of an IC can then be designed into whatever area that guarantees the best performance.

Wafers and components made from silicon carbide (SiC), on the other hand, are known to have good high-voltage, high-frequency and thermal-conductivity properties. However, serious limitations exist with regard to the manufacture of ICs in this material due to the fact that the number of components that can possibly be included is presently limited. Furthermore, standardized methods for an industrial manufacture of SiC ICs are not yet available in contrast to the situation for Si wafers.

As of today, SiC wafers of acceptable quality can only be manufactured with the help of very costly processes. This is related to the fact that most known processes give rise to large numbers of “pipes” in the material. Such defects have serious consequences for the electrical properties of the material and must therefore be avoided. Prime wafers of SiC are consequently quite expensive, which makes it desirable to try to limit the amount of material needed for the manufacture of SiC components as much as possible. Attempts have been made to achieve this by bonding a thin layer of SiC to a bulk Si wafer (Tong, Q.-Y. Lee, T.-H., Huang, L.-J., Chao, Y.-L. and Gösele, U. “Si and SiC layer transfer by high temperature hydrogen implantation and lower temperature layer splitting”, Electronics Letters, v. 34, nr 4, (1998), p 407-8). Although this makes it possible to take advantage of the excellent electrical properties of the SiC without an excessive consumption of material, the limited thermal conductivity of the Si substrate still poses a serious problem. Another way of limiting the amount of material used is to use wafers with small diameters, such as 2″ or 3″ wafers. However, serious limitations then arise in connection with the manufacture of components, since commercial production equipment is no longer available for such small diameters.

Attempts to solve the abovementioned problems are known. Thus, a thin layer of crystalline Si attached to an SiC wafer, either directly or with an intermediate layer of e.g. Si, silicon dioxide or diamond has been described in U.S. Pat. Nos. 6,521,923 and 6,497,763 as well as in an article in Compound Semiconductor, November 2005, pp 24-6. The single-crystal Si layer can be nominally stress-free or it can be under stress. Although poly-Si was used as a possible intermediate layer when bonding the single-crystal Si layer to the SiC wafer, this was only made in order to simplify a previous planarization of the surface of the SiC wafer. The reason for this is that SiC is extremely hard and therefore difficult to polish, whereas Si is soft enough to give a surface perfect for bonding after, for example, Chemical Mechanical Polishing (CMP).

SiO₂ has also been used as a planarizable intermediate layer in connection with the bonding of a single-crystal Si layer to an SiC wafer. Although the SiC substrate itself is a good heat conductor, such an intermediate layer bring back the heat-flow problem, since SiO₂ is such a poor heat conductor that already a thin layer will severely negate the good heat conductivity of the substrate.

With regard to materials for high-power radio frequency (RF) circuits, losses due to the electromagnetic fields constitute a very serious problem. The capacitive coupling between the conductors and the substrate will give rise to severe reductions in the useful signal unless high-ohmic Si substrates are used. Likewise, there will be serious loss of useful power due to the resistive losses generated by the induced substrate currents. To some extent, it has been possible to limit these losses in Si substrates by the use of SOI wafers. But the SiO₂ layer present in the SOI wafers will, as mentioned above, severely obstruct the flow of heat from component to substrate. Although the heat-flow problem can be solved by building the RF components in the abovementioned Si—SiC combination, such a solution alone is not electrically ideal. Numerous attempts have been made to solve the critical electrical-optimization problem for RF components. However, they all suffer from the lack of a simultaneous optimization of the thermal problems. In the case of RF components made from, e.g., GaAs, InP and GaN, it is quite common to isolate the active components from each other by removing the surrounding material by means of etching. The components thus appear in the form of mesas distributed over the chip surface. Techniques exist where the capacitive coupling to the substrate is reduced by having the electrical conductors run between the mesas in the form of air bridges with no dielectric under. Another example of the use of air-bridges is for RF heterojunction bipolar transistors in silicon-germanium. It is clear that the introduction of such bridging-type connections leads to a substantially more complicated manufacturing process.

Isolation of components by forming mesas is also used for components in SOI wafers, where trenches through the silicon layer and down to the buried oxide layer surround the mesas. However, the oxide under the mesas gives rise to the usual problems with adequate heat removal.

The fact that one goes to such extremes as to use electrical conductors in the form of bridges illustrates how important the design of the conductors is for the performance of the circuit. In order to obtain interconnects with low attenuation, it is common to use a thick insulator between the silicon substrate and the metal layers above. Sufficiently thick insulating layers cannot always be manufactured from SiO₂, however. Instead, one has to resort to polymers like polyimide, which introduces additional complexity into the production process. Another means of obtaining low attenuation is to use a conducting ground-plane in the form of a highly doped substrate or a buried metal layer. Although simpler to implement than air-bridges, these solutions also introduce a substantial complexity into the manufacturing process.

As an example of commercially available components suffering from problems regarding insufficient heat removal as well as excessive resistive and capacitive losses in the conductors, Laterally Diffused Metal Oxide Semiconductor (LDMOS) are mentioned. There are companies that manufacture their LDMOS circuits in epitaxial layers on highly doped bulk-silicon substrates using conventional IC design and manufacturing methods. Attempts to improve the situation have been made in that SOI substrates have been used. The underlying bulk substrate has then been low-to-medium doped with resistivities in the range 10-10³ ohmcm. However, serious problems then arise in that the substrate under the buried oxide layer can be influenced by charged carrier traps at the interface between the buried oxide layer and bulk silicon substrate, if not by the bias potentials applied to the components. Unintended inversion, depletion or accumulation can then take place in the surface region of the bulk substrate. This will, among other things, influence the efficiency of the LDMOS substantially. It has recently been shown that if the silicon substrate in the SOI wafer is given a low resistivity, the RF efficiency is drastically improved (Ref.: J. Ankarcrona et al, “Low Resistivity SOI for Improved Efficiency of LDMOS”, Proc. EUROSOI Workshop, pp. 69-70 (March 2006)). The high doping level of the substrate eliminates the above-mentioned inversion, depletion or accumulation at the interface. However, this only works for certain specific combinations of doping levels in the LDMOS transistor itself. The problems associated with the poor heat-conduction of SiO₂ remain.

As to integration of components made from different materials on one single IC chip, using combinations like, e.g., Si—GaAs, Si—GaN and Si—SiC, no applications of any type are know as of today.

### SUMMARY OF THE INVENTION

The object of the invention is to solve the problems and shortcomings discussed above.

This in attained by the hybrid wafer according to the invention in that it comprises a single-crystal SiₓGe₁₋ₓ layer, where 0≦x≦1, a high thermal conductivity layer, and between the single-crystal SiₓGe₁₋ₓ layer and the high thermal conductivity layer, an intermediate layer having a thickness of between 1 nanometer and 1 micrometer and comprising at least one amorphous or polycrystalline SiₓGe₁₋ₓ layer, where 0≦x≦1.

In one embodiment, said single-crystal SiₓGe₁₋ₓ layer comprises a first sublayer having a distinct first x value and at least one second sublayer having either a distinct second x value or a specific range of x values.

In one embodiment, said SiₓGe₁₋ₓ layer comprises at least one pre-manufactured IC component.

In one embodiment, said intermediate layer is doped to a specific electric conductivity forming an electrically conductive layer.

In one embodiment, said intermediate layer also comprises a silicon oxide based layer.

In one embodiment, said high thermal conductivity layer comprises either prime or secondary quality crystalline material or polycrystalline material.

In one embodiment, said crystalline or polycrystalline material is either semi-insulating or doped to a specific electric conductivity.

In one embodiment, a diamond-like layer is provided between said intermediate layer and said high thermal conductivity layer.

In one embodiment, said high thermal conductivity layer is AlN layer.

In one embodiment, said high thermal conductivity layer is a diamond layer.

In one embodiment, said high thermal conductivity layer is an SiC layer.

In one embodiment, it comprises an RF power transistor structure, said electrically conductive layer in contact directly or via said silicon oxide based layer with said high thermal conductivity layer forming a thermal path from said RF power transistor structure.

In one embodiment, said electrically conductive layer extends outside the RF power transistor structure forming part of an electric connection to said RF power transistor structure.

In one embodiment, said electrically conductive layer is located only below said RF power transistor structure.

In one embodiment, it comprises a combination of active and passive components, said electrically conductive layer in contact directly or via said silicon oxide based layer with said high thermal conductivity layer forming a thermal path from said combination of active and passive components.

In one embodiment, said electrically conductive layer extends outside said combination of active and passive components forming part of an electric connection to said combination of active and passive components.

In one embodiment, said electrically conductive layer is located only below said combination of active and passive components.

In one embodiment, it comprises at least one IC SiC component in at least one opening in said SiₓGe₁₋ₓ layer and said intermediate layer, and at least one IC SiₓGe₁₋ₓ component in said SiₓGe₁₋ₓ layer, said at least one IC SiC component and said at least one IC SiₓGe₁₋ₓ component together forming at least one hybrid IC structure.

In one embodiment, it comprises at least one IC component in a layer in at least one opening in said SiₓGe₁₋ₓ layer and said intermediate layer, at least one IC SiC component in at least one opening in said SiₓGe₁₋ₓ layer and said intermediate layer, and at least one IC component in said SiₓGe₁₋ₓ layer, said at least one IC component in said layer, said at least one IC SiC component, and said at least one IC SiₓGe₁₋ₓ component together forming at least one hybrid IC structure.

In one embodiment, it comprises at least one IC component in a layer in at least one opening in said SiₓGe₁₋ₓ layer and said intermediate layer, and at least one IC component in a layer on at least part of said SiₓGe₁₋ₓ layer, said at least one IC component in said at least one opening, and said at least one IC component on said at least part of said SiₓGe₁₋ₓ layer together forming at least one hybrid IC structure.

In one embodiment, it comprises at least one IC component in a layer in at least one opening in said SiₓGe₁₋ₓ layer and said intermediate layer, at least one IC SiC component in at least one opening in said SiₓGe₁₋ₓ layer and said intermediate layer, and at least one IC component in a layer on at least part of said SiₓGe₁₋ₓ layer, said at least one IC component in said at least one opening, said at least one IC component on said at least part of said SiₓGe₁₋ₓ layer, and said at least one IC SiC component together forming at least one hybrid IC structure.

### BRIEF DESCRIPTION OF THE DRAWING

The invention will be described more in detail below with reference to the appended drawing on which

FIG. 1 depicts part of one embodiment of the present invention involving the manufacture of a hybrid wafer according to the invention,

FIG. 2 shows an embodiment of a hybrid wafer according to the invention,

FIG. 3 illustrates the utilization of the hybrid wafer according to the invention for the manufacture of integrated circuit components in SiₓGe₁₋ₓ as well as SiC,

FIG. 4 depicts one embodiment of the present invention involving the actual manufacture of IC components in the SiₓGe₁₋ₓ layer and in the SiC wafer,

FIG. 5 illustrates the utilization of the hybrid wafer according to the invention for an additional integration of IC components of materials from the III-V groups in the periodic table,

FIG. 6 illustrates the addition of GaN components in a grown GaN layer,

FIG. 7 depicts part of one embodiment of the invention involving the manufacture of thermally optimized RF power components in the hybrid wafer,

FIG. 8 depicts one embodiment of the invention involving the manufacture of electrically as well as thermally optimized RF power components in the hybrid wafer according to the invention,

FIG. 9 depicts another embodiment of the invention involving the manufacture of electrically as well as thermally optimized RF power components in the hybrid wafer according to the invention, and

FIG. 10 is a graphical illustration of the relationship between series resistance and output resistance of an RF power component.

### DESCRIPTION OF THE INVENTION

As a background, a brief description is first given of methods for making hybrid wafers according to the invention.

As an example, a high thermal conductivity layer or wafer, e.g. a silicon carbide (SiC) wafer, is chosen as the starting point. Not only prime single-crystal SiC wafers can be used, but also seconds, polycrystalline and sintered wafers. Apart from the apparent cost savings, this imparts flexibility in that wafer sizes compatible with current IC-processing equipment can be used.

If so desired, the otherwise excellent heat conduction properties of the SiC wafer can at this stage be enhanced by a diamond-like coating. Such a coating has a heat conductivity that is typically 4-5 times that of the SiC wafer. It will therefore not only provide an easy path into the SiC wafer for the heat generated by electrical components, but will also facilitate a rapid lateral spreading of the heat. The diamond layer thereby smoothes out local peaks in the heat-distribution, if such peaks are present due to some components having an exceptionally high power-dissipation.

That surface of the SiC wafer or the composite diamond-coated SiC wafer, as the case may be, which is to be bonded to a transferred Si layer is first coated with an Si layer consisting of polycrystalline or, preferably, amorphous Si. This layer will for simplicity be referred to as a poly-Si layer. The layer can be deposited by means of, for example, Chemical Vapor Deposition (CVD) or Physical Vapor Deposition (PVD). The poly-Si layer is prepared for its intended final use by the implantation of dopant atoms. In cases where the poly-Si layer is to have n-type conduction, the implanted atoms can be any one or all of phosphorus (P), arsenic (As) or antimony (Sb). If p-type conduction is preferred, the implanted atoms can be any one or all of boron (B), aluminum (Al), gallium (Ga) or indium (In). Alternatively, the dopant atoms can be introduced in situ, i.e. concurrently with the deposition of the poly-Si layer. In all cases, the preferred level of doping is so large that it will lead to a degenerate or almost degenerate gas of charge carriers in the poly-Si layer after completed processing. Such preferred carrier concentrations fall in the range 10¹⁸-10²⁰ cm⁻³. However, as will be clear from the over-all description of the invention, it does not exclude lower doping levels, or even undoped poly-Si. The doped poly-Si layer can be thermally activated at this stage or at a later stage. The surface of the poly-Si layer can be planarized, e.g. by means of Chemical Mechanical Polishing (CMP), to a Root Mean Square (RMS) smoothness of preferably not more that 10 Å. This can be done before as well as after the introduction of the dopant in the poly-Si layer

The CMP step takes advantage of the mechanical properties of the poly-Si layer compared to those of the underlying SiC surface. The limited hardness of the poly-Si layer makes it much easier to polish than the extremely hard SiC surface.

A handle wafer to be used in the layer transfer process consists of an Si wafer prepared to a quality level representative of standard semiconductor manufacturing, but with a front surface that has an RMS smoothness of, preferably, 10 Å. The surface of the wafer can, if necessary, have a poly-Si layer similar to that on the surface of the SiC wafer. An Si layer of the required thickness can be separated from the Si handle wafer in many ways. One is to use the so called “Smart Cut” method. In this case, the wafer is further prepared by implanting hydrogen ions through the front surface to a depth which defines the thickness of the Si layer to be transferred. As an alternative to this, the thickness of the Si layer to be transferred is defined by means of the formation of an etch-stop layer inside the handle wafer. Such an etch-stop layer can consist of a crystalline layer of silicon-germanium (SiGe), on top of which the single-crystal Si layer has been grown. Still another alternative is to use the buried oxide layer in an SOI wafer as the etch-stop layer. From this it follows that the transferred layer can also be under mechanical strain. Typical Si layer thicknesses fall in the range 0.01-10 μm.

The prepared surface of the handle wafer is placed in contact with the prepared surface of the SiC wafer. If the preparations are properly done, the two surfaces will adhere to each other instantaneously. The two wafers can also be pressed together if deemed necessary. The two-wafer package is then subjected to a judiciously selected heating cycle that will cause: 1) an increase in the strength of the atomic bonding of the two surfaces, 2) a transformation of the poly-Si layer to a, recrystallized layer with slightly or largely increased grain sizes with defects suitable for impurity gettering, 3) an activation of the dopant atoms in the recrystallized poly-Si layer and 4) a splitting-off of the Si layer from the handle wafer if the SmartCut method is to be used. The heat treatment is best accomplished by means of Rapid Thermal Annealing (RTA). Typical temperatures fall in the range 900-1100° C. The heating cycle can also be performed in a furnace at a single temperature, or by means of a series of consecutive temperature steps. Preferred temperatures and times for these steps fall in the range 600-1100° C. and 80-20 min. It is important to select the parameters for the thermal treatment in such a way that the original poly-Si layer recrystallizes into a large-crystal layer with plenty of defects localized inside the grains for optimum gettering performance. It was discovered that, with a judicious choice of the thermal treatment procedure, the formation of a recrystallized layer with such properties is facilitated by the stresses within the poly-Si layer during the thermal treatment. These stresses arise due to the fact that the poly-Si layer is confined between two rigid surfaces, namely that of the handle wafer and that of the SiC wafer.

It follows from the description above that either one or both of the surfaces that are to be bonded together can be coated with an Si layer consisting of polycrystalline or, preferably, amorphous Si, also referred to as “poly-Si” above for simplicity. After bonding, said poly-Si layer or layers, as the case may thus be, forms or form an intermediate poly-Si layer at the interface between the SiC wafer, or the composite diamond-coated SiC wafer as the case may be, and the Si layer.

The above-mentioned gettering effect of the recrystallized layer will manifest itself during the process of manufacturing of IC components. Inevitable impurity atoms that are introduced in the single-crystal device layer during processing will during the heat treatments migrate down to and bind with the local defects in the recrystallized layer. There, the impurity will be out of harm's way with respect to the vital parts of the IC components in the surface. In the absence of such intentionally generated gettering sites, the impurity atoms will most likely collect at the interfaces of the parts that make up the IC components.

In cases other than that of the SmartCut method, the bulk of the handle wafer and the etch-stop layer are removed by means of selective etching. Finally, the surface of the transferred Si layer can be polished by means of CMP to a smoothness appropriate for subsequent semiconductor processing. The hybrid wafer is now ready for the manufacture of components.

A slightly different method will be necessary if a device layer containing processed IC components is to be transferred from an Si-based wafer in order to form a hybrid wafer. In this case, the surface of the processed IC wafer is attached to the wafer that is to serve as a handle wafer by means of a suitable polymer, e.g. a photoresist. The processed IC wafer is then thinned from the back side by means of mechanical grinding combined with a chemical etch or a plasma etch down to a built-in etch-stop layer in the processed IC wafer. Such an etch-stop layer can consist of a crystalline layer of silicon-germanium (SiGe) on top of which a single-crystal Si layer has been grown before the start of the IC process. Still another alternative is to use the bulk oxide layer of an SOI wafer as the etch-stop layer. Typical single-crystal Si layer thicknesses fall in the range 0.01-10 μm. The surface of the so prepared handle wafer is then placed in contact with the surface of the SiC wafer. As was the case above, either one or both surfaces can have a coating of poly-Si as a part of the surface preparation. If properly prepared, the two surfaces will adhere to each other instantaneously. The two wafers can also be pressed together if deemed necessary. The two-wafer package can then be subjected to a judiciously selected heating cycle in order to increase the strength of the atomic bonding of the two surfaces. The handle wafer is then separated from the device layer containing the processed IC components by chemical dissolution of the polymer. Additional heating can then be used for optimization of the bond strength as well as the properties of the intermediate layer.

This exemplifies the major steps in the realization of a hybrid wafer with an optimized recrystallized poly-Si interface according to the invention.

Unlike the case with hybrid wafers having a device layer containing processed IC components, components now have to be manufactured in the single-crystal Si layer. When this has been done, the continued processing of the two types of hybrid wafers is the same.

Although the above description of the making of hybrid wafers according to the invention concentrated on SiC wafers, it should be pointed out that other wafer materials showing high thermal conductivity can also be used. Examples are wafers made from Group III nitrides, i.e. AlN, GaN and InN. Another example is wafers made of diamond. As was the case with the SiC wafers, prime single-crystal, seconds, polycrystalline and sintered wafers can be used in the form of pure compounds or mixtures. A recent reference to the literature is: L. J. Showalter et al, “Fabrication of Native Single-Crystal AlN Substrates”, Proc 21st Century COE Joint Workshop on Bulk Nitrides, IPAP Conf. Series 4, pp. 38-40 (June 2004).

The description above of a possible realization of a hybrid wafer also referred to crystalline layers and handle wafers consisting of Si. It should be clear, however, that this implies no limitation on the invention, since, more generally, SiₓGe₁₋ₓ with 0≦x≦1 can be used.

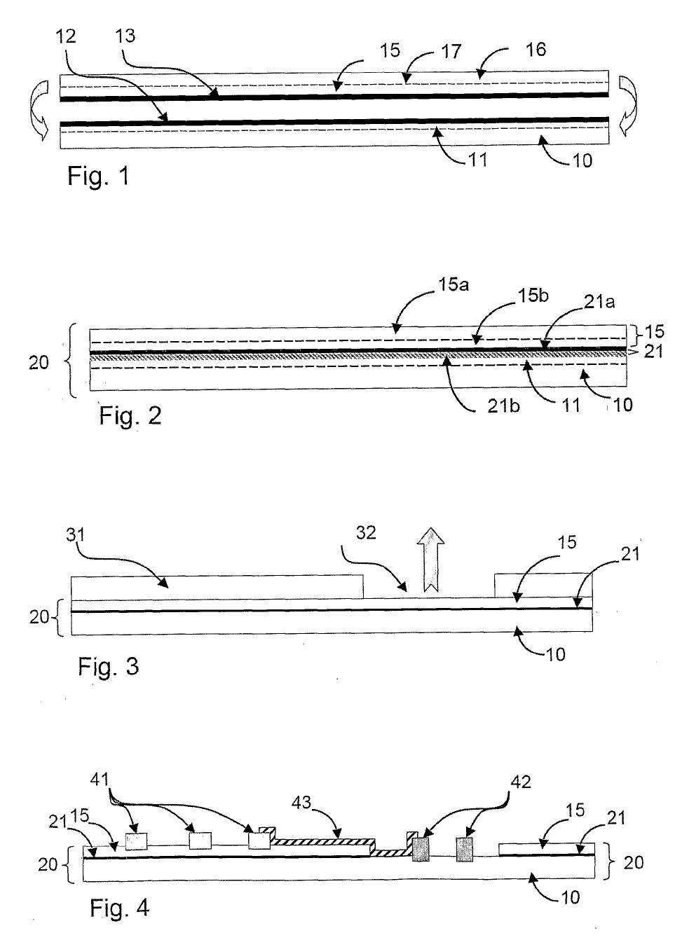

In order to introduce concepts used to further illustrate the invention, the abovementioned general description of ways to realize the invention will now be detailed with the help of FIG. 1.

As starting point an SiC wafer 10 is chosen, for which any one or a combination of the following alternatives exist: a prime or second quality single-crystal SiC wafer of any one of the crystallographic types 4H, 6H or 3C, a prime or second quality polycrystalline SiC wafer, a prime or second quality single-crystal SiC wafer of any one of the crystallographic types 4H, 6H or 3C coated with a diamond-like layer 11, a prime or second quality polyciystalline SiC wafer coated with a diamond-like layer 11. Typical thicknesses for the diamond-like layer 11 fall in the range 1-10 μm. The SiC wafer 10, with or without the diamond-like layer 11, is coated with a layer 12 of polycrystalline or, preferably, amorphous Si. This layer will in the following be denoted poly-Si layer 12 for brevity. The polycrystalline or amorphous Si layer can be deposited by means of CVD or PVD. If so desired, dopant atoms can be added in connection with the deposition process. Typical thicknesses and dopant concentrations for poly-Si layer 12 fall in the ranges 0.01-10 μm and 10¹⁸-10²⁰ cm⁻³, respectively. The poly-Si layer 12 can also be left undoped.

The other starting point is a handle wafer 16. Handle wafer 16 has at least a surface layer 15 of appropriate thickness consisting of single-crystal Si with electrical and mechanical properties typical for semiconductor manufacturing. For further enhancement of the properties consistent with the invention, surface layer 15 can be coated with a layer 13 of polycrystalline or, preferably, amorphous Si. This layer will in the following be denoted poly-Si layer 13 for brevity. Poly-Si layer 13 is deposited by the same methods as, and has properties similar but not necessarily equal to, those of poly-Si layer 12. The surface layer 15 on handle wafer 16 which will form the single-crystal Si surface-layer in the finished hybrid wafer is for brevity referred to as single-crystal Si layer 15. This layer can be the surface layer of a bulk single-crystal Si wafer. It can also be a single-crystal Si layer with or without mechanical strain which has been obtained by a first deposition of a layer of single-crystal SiₓGe₁₋ₓ having a continuously varying composition x, in the range 0.5-1 on a single-crystal Si wafer, followed by a deposition of a single-crystal layer of Si. If the separation of the single-crystal Si layer 15 is done by means of the Smart Cut method, an ion-implantation also forms part of the preparation of the handle wafer 16. The implanted ions will define the thickness of single-crystal Si layer 15 by being accumulated in a narrow region 17. Single-crystal Si layer 15 can also be part of an SOI wafer, in case of which the layer is separated from the handle wafer by an oxide layer located in region 17.

Poly-Si layer 12 can be polished, e.g. by means of CMP, to an RMS roughness preferably not exceeding 1 nm in order to prepare the surface for the subsequent bonding. Mechanically, the presence of poly-Si layer 12 is part of the optimization underlying the invention in that it eliminates the need for polishing the surface of the SiC wafer 10. The latter surface is mechanically extremely hard and therefore very difficult to polish. Since polishing techniques for SiC do exist, it is however possible to polish the surface of the SiC-wafer and forgo poly-Si layer 12. Dopant atoms that were not added previously can be added to poly-Si layer 12 by means of ion implantation.

Poly-Si layer 13, if present, is treated in manners similar to those of poly-Si layer 12.

Handle wafer 16 is oriented such that single-crystal Si layer 15, with or without a poly-Si layer 13, faces SiC wafer 10, the latter being with or without poly-Si layer 12. The two wafers are then brought into contact and will adhere spontaneously if the surfaces have been treated properly. If necessary, the wafers can be clamped together. The wafers will be more strongly bonded in a heat-treatment cycle that can either be based on RTA or furnace annealing. The heat-treatment cycle is designed in such a way that not only is bonding promoted, but also re-crystallization of the poly-Si into large-grained poly-Si, as well as activation of any dopant atoms in the poly-Si. In the case of RTA, the preferred temperatures and times to obtain this fall in the ranges 900-1100° C. and 10-30 seconds, respectively. In the case of furnace annealing, the preferred temperatures and times fall in the ranges 600-1100° C. and 80-20 minutes, respectively. In the case of the Smart Cut method, the heat-treatment cycle also involves the separation of single-crystal Si layer 15 from handle wafer 16. Another method for obtaining separation of single-crystal Si layer 15 is removal of the back part 14 of handle wafer 16 by means of CMP. Still another way is selectively etching away handle wafer 16 down to a previously introduced etch-stop layer 17. Etch-stop layer 17 can be a SiₓGe₁₋ₓ layer, where x is 0.25-1, and which is introduced prior to the deposition of single-crystal Si layer 15 on handle wafer 16. Etch-stop layer 17 can also consist of the oxide layer that forms part of an SOI handle wafer. The etch-stop layer is then removed by an additional selective-etching step.

In FIG. 2, SiC wafer 10 with its coating of a diamond-like layer 11 and single-crystal Si layer 15 is joined by an intermediate layer 21. Intermediate layer 21 consists of poly-Si and was formed from poly-Si layers 12 and 13 in FIG. 1 during the heat-treatment cycle. In FIG. 2, single-crystal Si layer 15 can also consist of single-crystal SiₓGe₁₋ₓ, with x having a specific value in the range 0≦x≦1. Alternatively, single-crystal Si layer 15 can also consist of a single-crystal SiₓGe₁₋ₓ sublayer 15a with x having a specific value in the range 0≦x≦1 on top of a single-crystal SiₓGe₁₋ₓ sublayer 15b with x having a range of values within the range 0≦x≦1. Likewise, intermediate layer 21 can consist of poly SiₓGe₁₋ₓ, with x having a specific or a range of values value in the interval 0≦x≦1. Intermediate layer 21 can also consist of one part in forms already described and denoted 21a in FIG. 2, and another part 21b, the latter being silicon oxide-based. The complete hybrid wafer, which consists of SiC wafer 10, diamond-like coating 11, intermediate layer 21 and single-crystal layer 15 are jointly denoted by 20 in FIG. 2 and subsequent figures.

The hybrid wafer according to the invention provides for an extensive degree of integration of components made from Si and SiC respectively. Thus, the single-crystal Si layer and the recrystallized poly-Si intermediate layer can be etched away to form openings to the underlying SiC. Here, SiC components can be made and also be connected to components in the single-crystal Si layer as needed. The result is an IC chip with Si and SiC components interconnected by the shortest possible signal paths, with the result that signal losses and time delays are minimized. The fact that the Si components in the present invention rest on a highly heat-conducting substrate means that they will be able to handle considerably higher power-levels than in the usual case, where the Si components are located on separate IC all-Si chips. An application well suited for this type of IC chip would be that of a power supply with SiC diodes controlled by adjacent Si electronics. Another application is that of SiC based sensors integrated with Si based signal-processing and control circuits for monitoring of processes in equipment and machinery running at elevated temperatures.

The hybrid wafer according to the invention provides for an integration driven even further. Thus, components made from III-V type of materials can be included on the same chip as the Si and SiC components. For this, openings are etched through the single-crystal Si layer and the recrystallized poly-Si intermediate layer as was the case for the SiC components. In these openings, GaN is grown, either on top of a pre-grown Si layer, or directly on the exposed SiC surface. Components are then made in the GaN layer and connections to the other components on the IC chip are established. The result is a single IC chip with any and all combinations of Si, GaN and SiC components possible. The components are hereby interconnected by conductor patterns forming the shortest possible signal paths. This means that signal losses and time delays will be minimized. The fact that the Si and GaN components now rest on a highly heat-conducting substrate means that they will be able to handle considerably higher power levels than in the usual case where these components are located on separate Si based IC chips. Although GaN has here been used as an example, materials such as GaN, AlGaN or AlN can be grown or deposited in the openings in combinations dictated by the requirements of the particular components to be manufacture in these openings.

The applications with substrate wafers made from Group III nitrides mentioned earlier do not exclude the use of SiC component integration in IC circuit chips. Such integration can still be obtained by building the necessary SiC components in deposited layers of SiC, analogously for the case for GaN above.

It should be noted that all grown or deposited layers referred to in this description can be in the form of amorphous, polycrystalline or single-crystal layers or combinations thereof, as required by the desired properties of the components to be built in these layers. The single-crystal layers can be in the form of a hetero- or homo-epitaxial layer, or combinations of such hetero- or homo-epitaxial layers.

For a more detailed description, FIG. 3 depicts an essential aspect of the invention which involves the utilization of hybrid wafer 20 for the manufacture of IC components in Si as well as SiC. FIG. 3 is a cross-section through SiC wafer 10, intermediate layer 21 and single-crystal Si layer 15. Hybrid wafer 20 has been coated with a layer of patterned photoresist 31 as part of the IC manufacturing process. A window 32 illustrates the patterned photoresist. Window 32 is used to selectively etch away the underlying part of single-crystal Si layer 15 and intermediate layer 21 as indicated by an arrow in order to reach SiC wafer 10. If SiC wafer 10 has a diamond-like coating 11, as was illustrated in FIG. 1, this coating is removed by means of plasma etching. After removal of photoresist 31, hybrid wafer 20 will have exposed Si areas adjacent to exposed areas with SiC.

FIG. 4 depicts one embodiment of the present invention with IC components in single-crystal Si layer 15 and in SiC wafer 10. Shown in FIG. 4 are Si components 41 built in Si layer 15 and SiC components 42 built in SiC wafer 10. The Si components 41 can be connected electrically to SiC components 42 by means of conductors 43 made from deposited and patterned metal films. In accordance with the invention, it is thus possible to obtain hybrid circuits where SiC components 42 communicate with and are electrically controlled by Si components 41 through a minimum of necessary electrical interconnects and with a highly efficient means of dissipating the heat generated in the components through the thermally highly conducting SiC wafer 10.

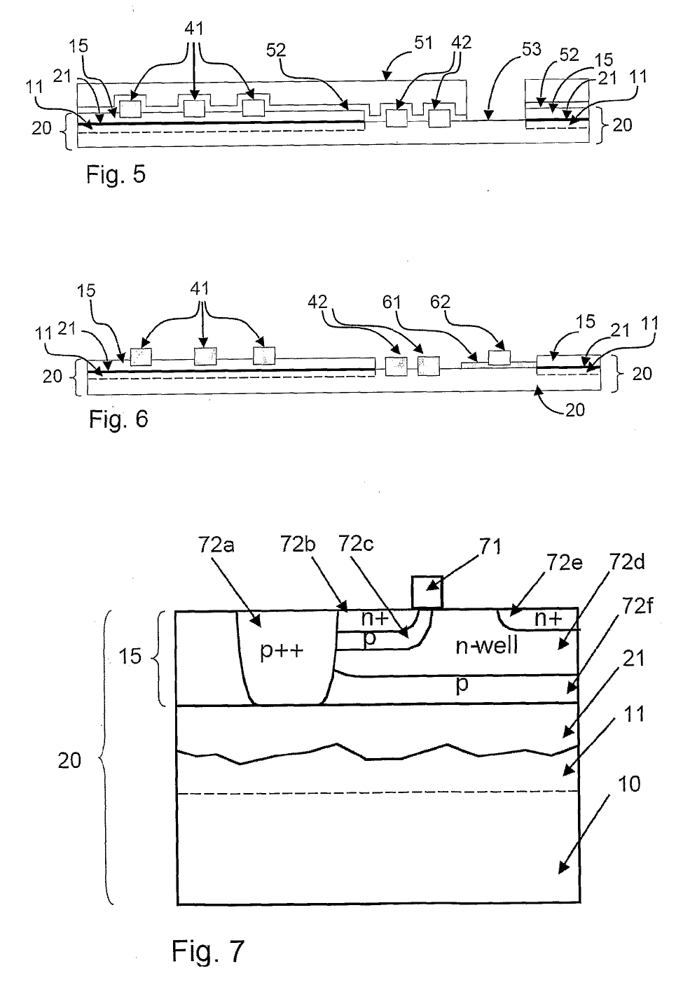

FIG. 5 depicts an essential part of the invention which involves the utilization of hybrid wafer 20 for an additional integration of IC components of materials from the III-V groups in the periodic table. The invention enables an integration of not only Si components 41 and SiC components 42, as already shown in FIG. 4, but of any combination of components based on Si, SiC and III-V. FIG. 5 illustrates one step in a process leading up to such an integration and shows how the already manufactured Si-based components 41 in single-crystal Si layer 15 and the SiC components 42 in SiC wafer 10 are covered by a protective layer 52. Protective layer 52 is preferably made from deposited silicon nitride or silicon dioxide or a mixture thereof. On top of protective layer 52, a layer 51 of photoresist is deposited and patterned. Shown in FIG. 5 is a window 53 in patterned photoresist 51. GaN or AlGaN is selectively grown in window 53, either directly on the SiC surface, or after a prior selective growth of an epitaxial Si film in window 53.

In FIG. 6, GaN-components 62 have been manufactured in the grown GaN or AlGaN layer 61. Protective layer 52 in FIG. 5 has been removed. The Si components 41, the SiC components 42 and the GaN components 62 can be connected electrically by means of conductors made from deposited and patterned metal films in patterns dictated by the circuit design. This illustrates an embodiment of the present invention with IC components of several materials on one single SiC-based wafer, thus permitting an integration of not only components of different kinds, but also of different materials on one single SiC chip, thus forming an highly integrated chip. Characteristics of the invention are the possibility to minimize the electrical interconnects and the highly efficient means of removing the heat generated in the multi-material components.

Before moving on to a detailed description of that part of the invention which involves electrical structures in the hybrid wafer, the general aspects of such structures will be presented.

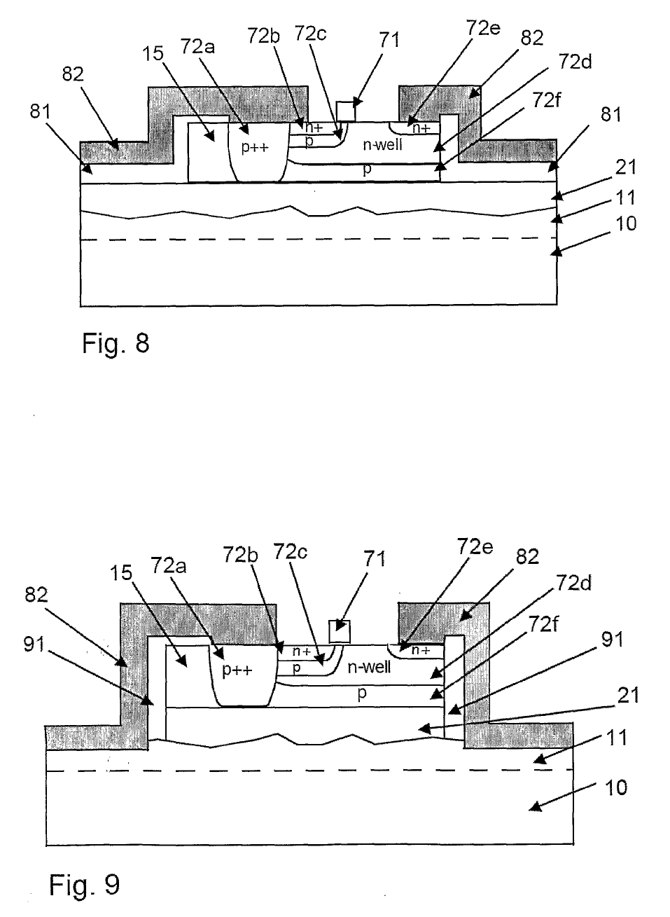

The hybrid wafer according to the invention with the optimized poly-Si intermediate layer and a single-crystal Si layer is used to manufacture RF power devices with vastly better thermal and electrical properties than would be the case for pure Si wafers. An example of such a device is an LDMOS transistor shown in FIG. 7. Shown in FIG. 7 is a cross-section of a hybrid wafer in that area of the single-crystal Si layer where the LDMOS transistor is located. The Si layer is to be envisioned as extending laterally in all directions around the LDMOS transistor and to contain similar or other active and passive components that constitute an IC. All electrical connections to and from the components, not shown in FIG. 7, are manufactured by means of deposited and patterned metals films which form one or more individually insulated conductive layers on the surface. The poly-Si intermediate layer is an active part of the transistor and can also form a buried-conductor and a ground-plane. For wafers with already-processed IC components in the transferred layer prior to bonding, as well as for wafers where the processing of the IC components was made after bonding, it holds that the electrical advantages of the invention are realized by etching islands in the single-crystal Si layer. These islands define individual or groups of active and passive components. The electrical connections to and from the components are made by means of deposited and patterned metal films forming one or more individually insulated layers directly on the surface of the hybrid wafer. Since the surface of the wafer consists of the exposed conducting recrystallized poly-Si layer from the interface of the hybrid, it is first coated with a dielectric layer of appropriate thickness in order to isolate it from the metallization. The resulting structure is illustrated in FIG. 8. As was previously the case, FIG. 8 only shows a single LDMOS transistor as an example. The other active and passive components that form the remaining parts of the IC will surround the transistor in all directions. An important distinction between FIG. 7 and FIG. 8, and an essential part of the invention, is that in the latter case, the interconnections are located on the surface of the hybrid wafer and not on the Si layer. In actual measurements, it is found that this aspect of the invention causes the resulting IC to have outstanding signal-handling capabilities.

From an electrical point of view, the aspect of the invention described so far utilizes a low-resistance design of the inevitable parasitic series resistance. The consequence is that the equivalent output resistance of a device such as the LDMOS will be high, thereby providing for an unusually efficient use of the electrical signal. Although this follows directly from measurements on the components themselves, it is not immediately obvious. However, an analysis in a publication by Ankarcrona et. al. (J. Ankarcrona, K.-H. Eklund, L. Vestling and J. Olsson, “Simulation and modeling of the substrate contribution to the output resistance for RF-LDMOS power transistors”, Solid-State Electronics, Vol. 48, No. 5, pp. 789-797, 2004) points in this direction. The following equation illustrates a relevant result from this publication in the form of a relationship between the parasitic series resistance R_{S}, the parasitic capacitance C_{S}, the frequency ω and the resulting equivalent output resistance of the component Rₚ:

$${R}_{P} = \frac{1}{{ω}^{2} {C}_{S}^{2} {R}_{S}} + {R}_{S}$$

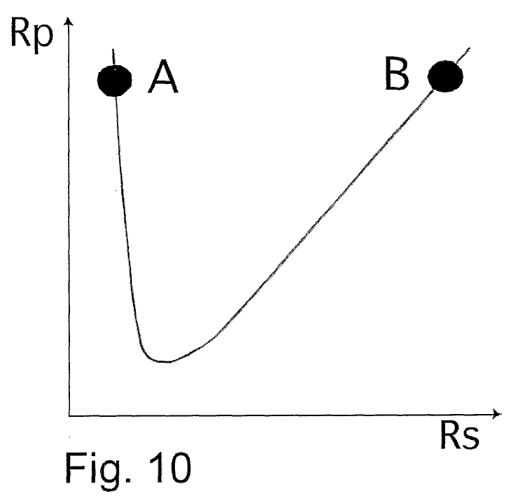

A graphical representation of the above equation is given in FIG. 10. The case described above in connection with FIG. 8 is in FIG. 10 represented by the leftmost circle and is denoted by “A”.

Another fundamental part of the invention uses a high-resistance design of the parasitic series resistance and is illustrated in FIG. 9 for a case of an LDMOS transistor. The recrystallized poly-Si intermediate layer is in this case etched away from all areas outside the component islands on the chip. The metallization now rests either directly on the SiC part of the hybrid wafer or on an intermediate SiO₂ layer. Therefore, semi-insulating SiC is needed for this approach of the invention. But the flexibility as to the quality of the SiC remains: single-crystal, polycrystalline or even irregular materials can still be used. The vertical sidewalls of the component islands are separated from the metallization by a deposited insulating layer. In this case as well, the equivalent output resistance of a device such as the LDMOS will be high, thereby providing for an efficient use of the electrical signal. Although this also follows directly from measurements on the components themselves, it is not immediately obvious. Reference is therefore made to the abovementioned publication and formula. In FIG. 10 the current case is represented by the rightmost circle and is denoted by “B”.

It should be noted that the two cases described above are not mutually exclusive. Parts of the IC chip can have components formed as islands with the recrystallized poly-Si intermediate layer removed and other parts with components where the layer remains.

After this presentation of general aspects of that part of the invention which involves electrical structures in the hybrid wafer, a more detailed description of such structures will now be presented with reference to FIGS. 7-10

Thus, FIG. 7 depicts part of one embodiment of the present invention involving the manufacture of RF power components in hybrid wafer 20. Shown in cross section in FIG. 7 is SiC wafer 10 with intermediate layer 21 and single-crystal Si layer 15. In single-crystal Si layer 15, an LDMOS component is built, as illustrated by gate structure 71 and various doped regions 72a-72f. The LDMOS component is taken to represent the whole class of possible active and passive IC components and is included not only because it illustrates all the manufacturing aspects of such IC components, but also because it illustrates the possibilities for electrical and thermal optimization inherent in the invention. This optimization is achieved by subsequent processing of the structure in FIG. 7. The structure as shown in FIG. 7 differs from an LDMOS component manufactured in a regular Si wafer in that SiC wafer 10 provides for a vastly more efficient cooling than would be the case for a Si wafer.

FIG. 8 depicts one embodiment of the present invention involving the manufacture of electrically and thermally optimized RF power components in the hybrid wafer. The present embodiment applies to hybrid wafers 20 having conducting or semi-insulating SiC, as well as to hybrid wafers 20 containing a diamond-like layer 11 on top of the SiC material. Shown in the cross section in FIG. 8 is SiC wafer 10 with diamond-like layer 11, intermediate layer 21 and single-crystal Si layer 15. In single-crystal Si layer 15, an LDMOS component is built as illustrated by gate structure 71 and the various dopings 72a-72f. For reason of simplicity, the LDMOS component in FIG. 8 has been provided with the same reference numerals as the LDMOS component in FIG. 7. Essential for the invention is that in FIG. 8, the LDMOS component 71, 72a-72e in single-crystal Si layer 15 is located in a discrete island. This has been obtained by a removal of parts of single-crystal Si layer 15 adjacent to the LDMOS structure for the purpose of electrical insulation. The removal of single-crystal Si layer 15 exposes intermediate layer 21. Since this layer in the present case is heavily doped and thus forms an electrically conducting layer, a dielectric layer 81 has been deposited on top of the exposed intermediate layer 21 as well as on the sidewalls of the LDMOS component for insulation. Electrical connections 82 to and from the component are made from patterned metal films deposited on top of dielectric layer 81.

FIG. 9 depicts another embodiment of the present invention involving the manufacture of electrically and thermally optimized RF power components in hybrid wafer 20. The present embodiment applies to hybrid wafers 20 with semi-insulating SiC or to hybrid wafers 20 containing a diamond-like layer 11 on top of the SiC material. Shown in cross section in FIG. 9 is SiC wafer 10 with diamond layer 11, intermediate layer 21 and single-crystal Si layer 15. In single-crystal Si layer 15, an LDMOS component is built as illustrated by gate structure 71 and the various dopings 72a-72f. For reason of simplicity, the LDMOS component in FIG. 9 has been provided with the same reference numerals as the LDMOS component in FIGS. 7 and 8. It should be noted that in FIG. 9, the LDMOS component 71, 72a-72e in single-crystal Si layer 15 is located in a discrete island, which has been obtained by removal of those parts of single-crystal Si layer 15 immediately adjacent to the LDMOS component. In addition, intermediate layer 21 has been removed and only remains beneath the LDMOS component and thus only inside the component island. Since SiC wafer 10 is semi-insulating or is insulated by diamond-like layer 1, the metals films for electrical connections 82 can be deposited directly on to the surface of the exposed SiC wafer 10 of diamond-like layer 11. Only the sidewalls of the component have to be insulated by a deposited dielectric film 91.

In order to increase the heat conductivity of the hybrid wafer even further, the hybrid wafer according to the invention can be thinned down from the back side after processing of the components. Other applications of back-side thinning are the addition to the back side of a ground plane at an appropriate distance from the components on the front side, or the adaptation of the chip so that it can become part of a waveguide.

The invention also allows via holes (not shown) to be formed through the hybrid wafer using laser drilling or plasma processing. These via holes can be used to connect front metal interconnects to the back-side of the hybrid wafer. For the LDMOS component in FIGS. 8 and 9, this would enable the source terminal, represented by doping region 72a, to be accessed from the back side of the hybrid wafer instead of by means of electrical conductors of the front side. This will reduce the inductive losses otherwise caused by the bonding wires.

1. A hybrid wafer, comprising
a single-crystal SiₓGe₁₋ₓ layer, where 0≦x≦1,
a high thermal conductivity layer, and
between the single-crystal SiₓGe₁₋ₓ layer and the high thermal conductivity layer, an intermediate layer having a thickness of between 1 nanometer and 1 micrometer and comprising at least one amorphous or polycrystalline SiₓGe₁₋ₓ layer, where 0≦x≦1.

2. The hybrid wafer according to claim 1, wherein said single-crystal SiₓGe₁₋ₓ layer comprises a first sublayer having a distinct first x value and at least one second sublayer having either a distinct second x value or a specific range of x values.

3. The hybrid wafer according to claim 1, wherein said SiₓGe₁₋ₓ layer comprises at least one pre-manufactured IC component.

4. The hybrid wafer according to claim 1, wherein said intermediate layer is doped to a specific electric conductivity forming an electrically conductive layer.

5. The hybrid wafer according to claim 1, wherein said intermediate layer also comprises a silicon oxide based layer.

6. The hybrid wafer according to claim 1, wherein said high thermal conductivity layer comprises either prime or secondary quality crystalline material or polycrystalline material.

7. The hybrid wafer according to claim 6, wherein said crystalline or polycrystalline material is either semi-insulating or doped to a specific electric conductivity.

8. The hybrid wafer according to claim 1, wherein a diamond-like layer is provided between said intermediate layer and said high thermal conductivity layer.

9. The hybrid wafer according to claim 1, wherein said high thermal conductivity layer is an AlN layer.

10. The hybrid wafer according to claim 1, wherein said high thermal conductivity layer is a diamond layer.

11. The hybrid wafer according to claim 1, wherein said high thermal conductivity layer is an SiC layer.

12. The hybrid wafer according to claim 9, wherein the hybrid wafer comprises an RF power transistor structure, and said electrically conductive layer is in contact directly or via said silicon oxide based layer with said high thermal conductivity layer forming a thermal path from said RF power transistor structure.

13. The hybrid wafer according to claim 12, wherein said electrically conductive layer extends outside the RF power transistor structure forming part of an electric connection to said RF power transistor structure.

14. The hybrid wafer according to claim 12, wherein said electrically conductive layer is located only below said RF power transistor structure.

15. The hybrid wafer according to claim 9, wherein the hybrid wafer comprises a combination of active and passive components, and said electrically conductive layer is in contact directly or via said silicon oxide based layer with said high thermal conductivity layer forming a thermal path from said combination of active and passive components.

16. The hybrid wafer according to claim 15, wherein said electrically conductive layer extends outside said combination of active and passive components forming part of an electric connection to said combination of active and passive components.

17. The hybrid wafer according to claim 15, wherein said electrically conductive layer is located only below said combination of active and passive components.

18. The hybrid wafer according to claim 11, wherein the hybrid wafer comprises at least one IC SiC component in at least one opening in said SiₓGe₁₋ₓ layer and said intermediate layer, and at least one IC SiₓGe₁₋ₓ component in said SiₓGe₁₋ₓ layer, said at least one IC SiC component and said at least one IC SiₓGe₁₋ₓ component together forming at least one hybrid IC structure.

19. The hybrid wafer according to claim 11, wherein the hybrid wafer comprises at least one IC component in a layer in at least one opening in said SiₓGe₁₋ₓ layer and said intermediate layer, at least one IC SiC component in at least one opening in said SiₓGe₁₋ₓ layer and said intermediate layer, and at least one IC component in said SiₓGe₁₋ₓ layer, said at least one IC component in said layer, said at least one IC SiC component, and said at least one IC SiₓGe₁₋ₓ component together forming at least one hybrid IC structure.

20. The hybrid wafer according to claim 11, wherein the hybrid wafer comprises at least one IC component in a layer in at least one opening in said SiₓGe₁₋ₓ layer and said intermediate layer, and at least one IC component in a layer on at least part of said SiₓGe₁₋ₓ layer, said at least one IC component in said at least one opening, and said at least one IC component on said at least part of said SiₓGe₁₋ₓ layer together forming at least one hybrid IC structure.

21. The hybrid wafer according to claim 11, wherein the hybrid wafer comprises at least one IC component in a layer in at least one opening in said SiₓGe₁₋ₓ layer and said intermediate layer, at least one IC SiC component in at least one opening in said SiₓGe₁₋ₓ layer and said intermediate layer, and at least one IC component in a layer on at least part of said SiₓGe₁₋ₓ layer, said at least one IC component in said at least one opening, said at least one IC component on said at least part of said SiₓGe₁₋ₓ layer, and said at least one IC SiC component together forming at least one hybrid IC structure.
